(19) United States
(12) Patent Application Publication
(10) Pub. No.: US 2026/0305252 A1
(43) Pub. Date: Oct. 1, 2026

(54) FILM-LIKE ADHESIVE AGENT, ADHESIVE FILM, DICING/DIE-BONDING INTEGRATED FILM, AND METHOD FOR PRODUCING SEMICONDUCTOR DEVICE

(71) Applicant: Resonac Corporation, Minato-ku, Tokyo (JP)

(72) Inventors: Shota AOYAGI, Tokyo (JP); Michiko KAYA, Tokyo (JP)

(21) Appl. No.: 19/479,350

(22) PCT Filed: Aug. 8, 2024
(86) PCT No.: PCT/JP2024/028497

§ 371 Date: Oct. 28, 2025

(30) Foreign Application Priority Data
Aug. 9, 2023 (JP) 2023-129974

(51) Int. Cl. H10P 72/70; H10P 58/00; H10W 72/00; H10W 72/30; H10W 90/00

(52) U.S. Cl. CPC H10P 72/7416; H10P 58/00; H10P 72/7404; H10W 72/354; H10W 90/732; H10W 90/734; H10W 72/07332; H10W 72/884; H10W 90/754

(57) ABSTRACT

A film-like adhesive agent is composed of a resin composition having a thermosetting property and containing a rubber component, the film-like adhesive agent having a first surface and a second surface, wherein the film-like adhesive agent has a region in a vicinity of the first surface, in which a content of the rubber component increases from a side of the second surface toward a side of the first surface, and a graph obtained by indentation measurement using an atomic force microscope has: a portion G1 in which an elastic modulus gradually increases starting from a measurement result at the first surface; and a portion G2 in which the elastic modulus is substantially constant from an end point of the portion G1.

### TECHNICAL FIELD

The present disclosure relates to a film-like adhesive agent, an adhesive film, a dicing/die-bonding integrated film, and a method for producing a semiconductor device.

### BACKGROUND ART

In recent years, with the increasing functionality and speed of smartphones, tablet PCs, and the like, the semiconductor packages used in them are required to be even smaller, have higher capacity, higher speed, and be thinner. In wafers used in such semiconductor packages, further miniaturization of wiring is progressing, and chips also tend to become even thinner during the assembly of semiconductor packages.

Amidst such trends, a problem has begun to emerge, particularly in the fields of DRAM and NAND flash memory, where extremely small amounts of heavy metal ions such as copper ions cause operational failures.

It has been known that when heavy metal ions come into contact with a silicon crystal, they can diffuse through the crystal and reach the circuit surface, thereby causing operational failures. From the viewpoint of preventing the occurrence of operational failures, it is common in the assembly of semiconductor packages to perform a gettering treatment on the silicon wafer to capture heavy metal ions so that they do not diffuse to the circuit surface.

As for the gettering treatment, for example, a method of providing a gettering layer inside the wafer (intrinsic gettering, hereinafter referred to as “IG”) and a method of providing a gettering layer on the back surface of the wafer (extrinsic gettering, hereinafter referred to as “EG”) are mainly used. However, with IG, the thickness of the gettering layer that can be formed inside has become smaller due to the thinning of chips, and its effect can no longer be said to be sufficient. Furthermore, with EG, since microcracks are formed on the back surface of the wafer, the flexural strength of the chip decreases. Therefore, a problem arises in that it is difficult to perform excessive gettering treatment, especially for extremely thin wafers that are difficult to handle. Under these circumstances, providing a gettering function for capturing heavy metal ions to a resin film (an adhesive film used in the manufacturing process of a semiconductor device), more specifically, a film-like adhesive agent (die bonding film) used for adhesion between a chip and a substrate or between chips, has been considered (see, for example, Patent Literatures 1 and 2).

### CITATION LIST

### Patent Literature

Patent Literature 1: Japanese Unexamined Patent Publication No. 2011-213878
Patent Literature 2: Japanese Unexamined Patent Publication No. 2012-241157

### SUMMARY OF INVENTION

### Technical Problem

However, conventional film-like adhesive agents are not sufficient in suppressing defects associated with the migration of copper ions within the adhesive, and there is still room for improvement. Furthermore, further improvement in the adhesive strength of the film-like adhesive agent is required. The present disclosure provides a film-like adhesive agent having a barrier function that impedes the migration of heavy metal ions, for example, copper ions, and excellent adhesion, and an adhesive film including the same. The present disclosure also provides a dicing/die-bonding integrated film including the film-like adhesive agent as a first adhesive layer, and a method for producing a semiconductor device using the same.

### Solution to Problem

A film-like adhesive agent according to a first aspect of the present disclosure is a film-like adhesive agent that is composed of a resin composition having a thermosetting property and containing a rubber component, and has a first surface and a second surface, wherein the film-like adhesive agent has a region in the vicinity of the first surface, in which a content of the rubber component increases from the second surface side toward the first surface side, and a graph obtained by performing indentation measurement using an atomic force microscope conducted according to the following procedure has a portion G1 in which an elastic modulus gradually increases starting from a measurement result at the first surface, and a portion G2 in which the elastic modulus is substantially constant from an end point of the portion G1.

### (Procedure for Indentation Measurement Using an Atomic Force Microscope)

(1) Cure the film-like adhesive agent, fix the cured film-like adhesive agent on a sample stage of an atomic force microscope, and set a cantilever in a cantilever holder.
(2) Press the cantilever to obtain a curve showing a relationship between an applied load and an indentation depth.
(3) Obtain the graph showing the relationship between an elastic modulus of the film-like adhesive agent and a distance from the first surface, from the curve, by using Hertz contact theory.

The state where the film-like adhesive agent is cured by heating means a state where the reaction rate is 90% or more in a general method for evaluating the degree of curing by comparing the amount of heat generated before and after the reaction by DSC (Differential Scanning calorimeter, for example, Thermo Plus 2 manufactured by Rigaku Corporation). To cure the film-like adhesive agent, it may be heated, for example, at 170° C. for 3 hours.

The film-like adhesive agent having the above region has a barrier function that impedes the migration of heavy metal ions and excellent adhesion. Although the reason for this is not necessarily clear, the present inventors speculate as follows. That is, the fact that the content of the rubber component in the above region located in the vicinity of the first surface is relatively large means, in other words, that in the vicinity of the first surface, a region with a relatively large content of the rubber component is locally formed in the thickness direction, while it is formed with a continuous spread in the planar direction. As a result, it can be said that the above region is denser than other regions, and it is presumed that having such a region with a certain thickness exhibits a barrier function that impedes the migration of heavy metal ions. Also, not only in the vicinity of the first surface, but also by increasing the elastic modulus of the bulk itself, the barrier function that impedes the migration of heavy metal ions tends to be more effectively exhibited.

Furthermore, it was found that when a graph showing a specific behavior is obtained when indentation measurement using an atomic force microscope is performed on the film-like adhesive agent, the adhesion of the film-like adhesive agent tends to be excellent. Although the reason for this is not necessarily clear, it is presumed that because the elastic modulus in the vicinity of the first surface is relatively smaller than that of other parts (that is, it is soft to some extent), the film-like adhesive agent deforms appropriately, and the adhesion between the film-like adhesive agent and an adherend tends to be excellent. It should be noted that as another method for improving adhesion, a method of increasing adhesive strength by adding a low-molecular-weight additive is generally known, but such a method often deteriorates the reliability of the semiconductor. Therefore, the film-like adhesive agent according to the present embodiment is preferable because it can improve adhesion without impairing reliability.

An adhesive film according to the present disclosure includes the above-described film-like adhesive agent and a base film in contact with the second surface of the film-like adhesive agent. A dicing/die-bonding integrated film according to the present disclosure includes, in this order, a first adhesive layer composed of the above-described film-like adhesive agent, a second adhesive layer in contact with the second surface of the film-like adhesive agent, and a base film in contact with the second adhesive layer.

A method for producing a semiconductor device according to the present disclosure includes a step of attaching a wafer onto the first surface of the film-like adhesive agent (first adhesive layer) in the dicing/die-bonding integrated film, a step of singulating the wafer and the film-like adhesive agent into a plurality of chips each with an adhesive piece, a step of picking up the chip with an adhesive piece from the second adhesive layer, and a step of pressure-bonding the chip onto a substrate or another chip via the adhesive piece.

### Advantageous Effects of Invention

According to the present disclosure, a film-like adhesive agent having a barrier function that impedes the migration of heavy metal ions, for example, copper ions, and excellent adhesion, and an adhesive film including the same are provided. Furthermore, according to the present disclosure, a dicing/die-bonding integrated film including the film-like adhesive agent as a first adhesive layer, and a method for producing a semiconductor device using the same are provided.

### BRIEF DESCRIPTION OF DRAWINGS

FIG. 1 is a cross-sectional view schematically showing an embodiment of a film-like adhesive agent according to the present disclosure.

FIG. 2 is an example of a graph obtained when a film-like adhesive agent according to the present disclosure is subjected to indentation measurement.

FIGS. 3(a) and 3(b) are examples of graphs obtained when indentation measurement is not performed correctly.

FIGS. 4(a) and 4(b) are examples of graphs obtained when indentation measurement is not performed correctly.

FIGS. 5(a) and 5(b) are examples of graphs obtained when indentation measurement is not performed correctly.

FIG. 6 is an example of a graph obtained when indentation measurement is not performed correctly.

FIG. 7 is a cross-sectional view schematically showing an example of an adhesive film including the film-like adhesive agent shown in FIG. 1.

FIG. 8 is a cross-sectional view schematically showing an embodiment of a dicing/die-bonding integrated film according to the present disclosure.

FIG. 9 is a cross-sectional view schematically showing an example of a semiconductor device.

FIG. 10 is a cross-sectional view schematically showing another example of a semiconductor device.

FIG. 11 is a cross-sectional view schematically showing another embodiment of a film-like adhesive agent according to the present disclosure.

### DESCRIPTION OF EMBODIMENTS

Hereinafter, embodiments of the present disclosure will be described with appropriate reference to the drawings. However, the present disclosure is not limited to the following embodiments. In the following embodiments, their constituent elements (including steps and the like) are not essential unless otherwise specified. The size of the constituent elements in each drawing is conceptual, and the relative relationship of the sizes between the constituent elements is not limited to that shown in each drawing.

The same applies to the numerical values and their ranges in this specification, and they do not limit the present invention. In this specification, a numerical range indicated using “to” indicates a range that includes the numerical values described before and after “to” as the minimum value and the maximum value, respectively. In the numerical ranges described in stages in this specification, the upper limit value or the lower limit value described in one numerical range may be replaced with the upper limit value or the lower limit value of another numerical range described in stages. Furthermore, in the numerical ranges described in this specification, the upper limit value or the lower limit value of the numerical range may be replaced with the value shown in the examples. In this specification, (meth)acrylate means acrylate or its corresponding methacrylate. The same applies to other similar expressions such as (meth)acryloyl group, (meth)acrylic copolymer, and the like.

### <Film-Like Adhesive Agent>

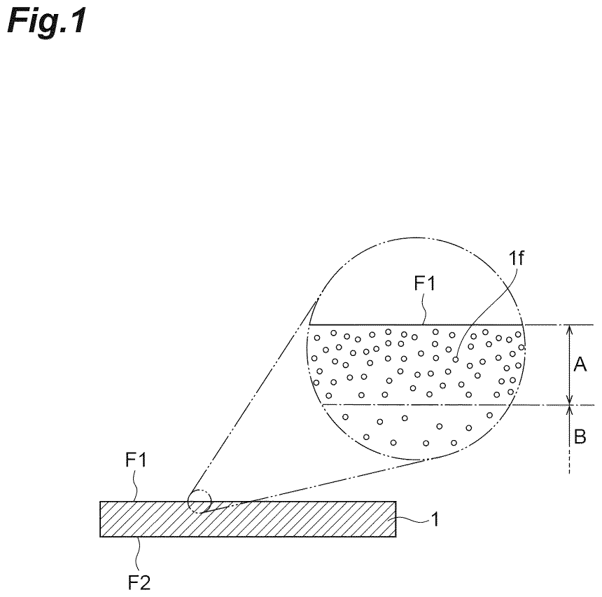

FIG. 1 is a cross-sectional view schematically showing a film-like adhesive agent according to the present embodiment. The film-like adhesive agent 1 shown in this figure has a single-layer structure composed of a resin composition having a thermosetting property and containing a rubber component. The film-like adhesive agent may have a multilayer structure. The thickness of the film-like adhesive agent 1 may be 50 μm or less, and may be, for example, 40 μm or less, 30 μm or less, 20 μm or less, or 10 μm or less. When the thickness of the film-like adhesive agent 1 is 50 μm or less, the distance between a semiconductor element and a support member on which the semiconductor element is mounted becomes shorter, which tends to make defects due to heavy metal ions more likely to occur, and thus the effects of the present invention are more easily obtained. The lower limit of the thickness of the film-like adhesive agent 1 is not particularly limited, but is, for example, 2 μm or more. When the thickness of the film-like adhesive agent 1 is 2 μm or more, a film with a better appearance tends to be more easily obtained.

The film-like adhesive agent 1 has, in the vicinity of the first surface F1, a region A (a region whose thickness is indicated by an arrow in the enlarged view shown in FIG. 1) in which the content of the rubber component increases from the second surface F2 side toward the first surface F1 side. The region A is constituted by a plurality of rubber components 1f and resin components other than the rubber component. In the region A, the content of the rubber component 1f may increase continuously or may increase stepwise. The region A plays a role of impeding the migration of heavy metal ions. That is, it can be said that the region A located in the vicinity of the first surface F1 is locally formed in the thickness direction, while it is formed with a continuous spread in the planar direction. Since such a region A is denser compared to other regions, it is presumed to have a barrier function that impedes the migration of heavy metal ions.

The region A varies depending on the thickness of the film-like adhesive agent 1, but is located at a position shallower than a position at a depth of 2 μm from the first surface F1. In other words, “in the vicinity of the first surface F1” in the present embodiment means a region shallower than a position at a depth of 2 μm from the first surface F1. It should be noted that it is sufficient that the region A exists in the vicinity of the first surface F1, and for example, a region where the content of the rubber component 1f is small may exist locally on the first surface F1.

The film-like adhesive agent 1 has a region B in which the content of the rubber component 1f does not substantially change in the direction from the region A toward the second surface F2 side. The region B is constituted by a plurality of rubber components 1f and resin components other than the rubber component.

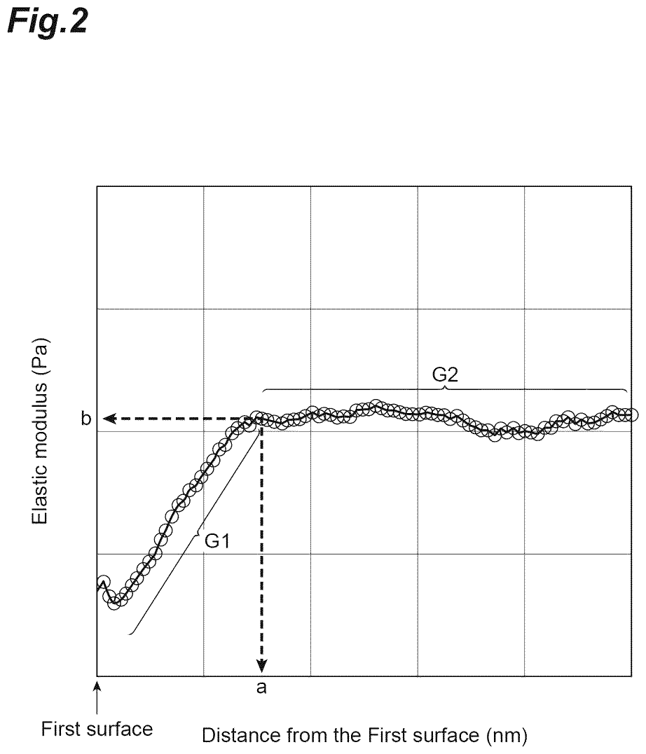

For the film-like adhesive agent 1, a graph (a graph as shown in FIG. 2) obtained by performing indentation measurement using an atomic force microscope conducted according to the following procedure has a portion G1 in which an elastic modulus gradually increases starting from a measurement result at the first surface F1, and a portion G2 in which the elastic modulus is substantially constant from an end point of the portion G1.

### (Procedure for Indentation Measurement Using an Atomic Force Microscope)

(1) The film-like adhesive agent 1 is cured, the cured film-like adhesive agent 1 is fixed on a sample stage of an atomic force microscope, and a cantilever is set in a cantilever holder.
(2) The cantilever is pressed in to obtain a curve showing a relationship between an applied load and an indentation depth.
(3) From the curve, a graph showing the relationship between the elastic modulus of the film-like adhesive agent and a distance from the first surface F1 is obtained using Hertz contact theory.

In procedure (1), as the atomic force microscope, for example, SPM400 manufactured by Hitachi High-Tech Corporation can be mentioned. As the cantilever, for example, SI-DF-40 manufactured by Hitachi High-Tech Corporation can be mentioned. A cantilever with a radius of curvature of 10 nm or less is used.

In procedure (2), a curve (force curve) showing the relationship between the applied load (load applied to the cantilever) and the indentation depth (displacement of the piezoelectric element) in the region where the cantilever is being pressed into the sample (cured film-like adhesive agent 1) is obtained. The indentation depth at this time may be, for example, 500 nm or more, or 1000 nm or more. The indentation depth is set to a depth that allows at least the region A to be grasped.

In procedure (3), the force curve of the indentation region obtained in procedure (2) is converted into a graph showing the relationship between the elastic modulus and the distance from the first surface (indentation depth of the cantilever) using Hertz contact theory. In a series of measurements, a corrected cantilever spring constant is used, the state of the cantilever is monitored, and if obvious wear, deterioration, or the like is observed, the cantilever is replaced.

The reason why a graph as shown in FIG. 2 is obtained by performing indentation measurement on the film-like adhesive agent 1 is as follows. That is, since the content of the rubber component 1f in the region A decreases from the first surface F1 side toward the second surface F2 side, the curve in FIG. 2 shows a tendency for the elastic modulus to gradually increase (G1 portion shown in FIG. 2). On the other hand, since the content of the rubber component 1f does not substantially change in the region B, which is a region deeper in the thickness direction than the region A (a region in the direction from the region A toward the second surface F2 side), the curve in FIG. 2 shows a substantially constant value for the elastic modulus (G2 portion shown in FIG. 2). It is considered that the film-like adhesive agent has excellent adhesion because the elastic modulus of the region A is smaller than that of the region B (that is, it is soft to some extent).

It is very difficult to produce a film-like adhesive agent for which a graph as shown in FIG. 2 is obtained by performing indentation measurement. Specifically, even if a film-like adhesive agent is produced using the same materials and under the same conditions, due to the influence of temperature and humidity conditions during production, temperature unevenness during drying of the film-like adhesive agent, and the like, a film-like adhesive agent for which a graph as shown in FIG. 2 is obtained when indentation measurement is performed may be produced, and at the same time, a film-like adhesive agent for which a graph as shown in FIG. 2 is not obtained when indentation measurement is performed may also be produced. However, by producing the film-like adhesive agent based on the method for producing a film-like adhesive agent described later, the yield of the film-like adhesive agent according to the present embodiment can be improved.

When the following (1) and (2) are satisfied, it can be determined that a graph as shown in FIG. 2 has been obtained for the film-like adhesive agent.
(1) From the start of the elastic modulus measurement (the left end of the graph; starting from the measurement result at the first surface), the elastic modulus increases substantially monotonically as the distance from the first surface increases (the graph showing the relationship between the elastic modulus and the distance from the first surface has a G1 portion as shown in FIG. 2).
(2) After the elastic modulus has increased substantially monotonically (from the end point of portion G1), the elastic modulus becomes substantially constant (the graph showing the relationship between the elastic modulus and the thickness of the film-like adhesive agent has a G2 portion as shown in FIG. 2).

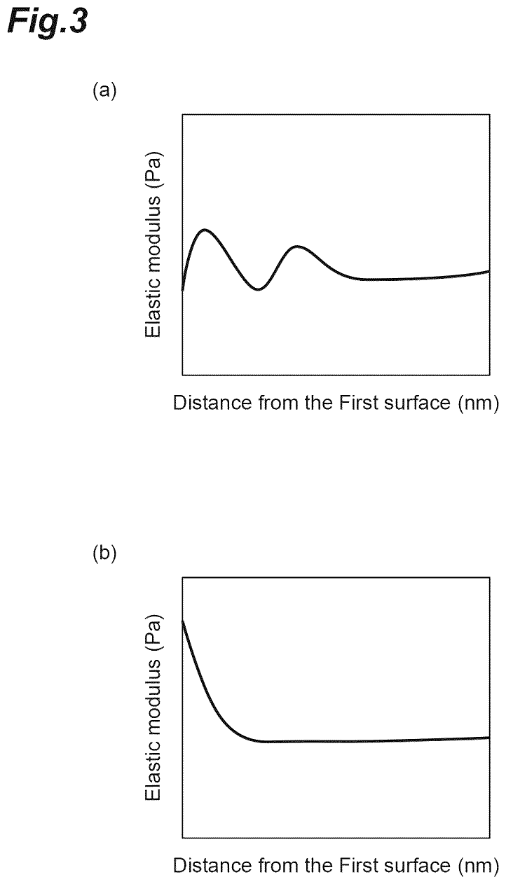

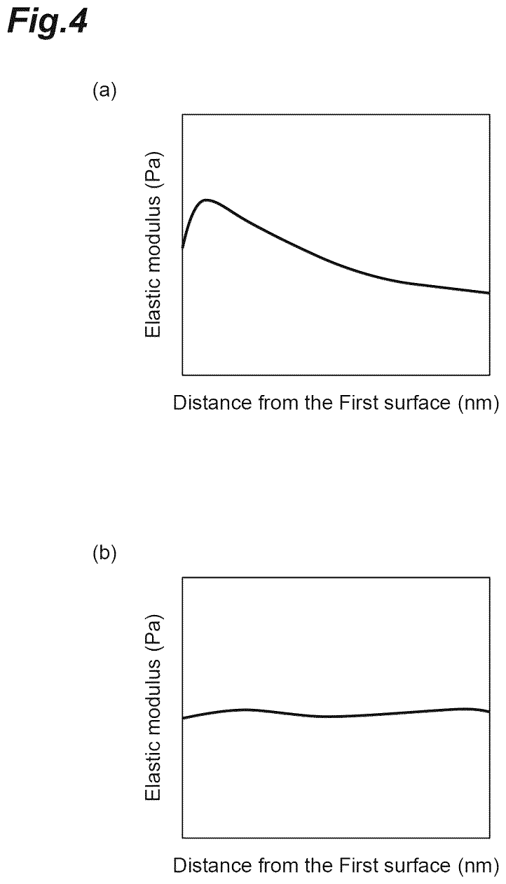

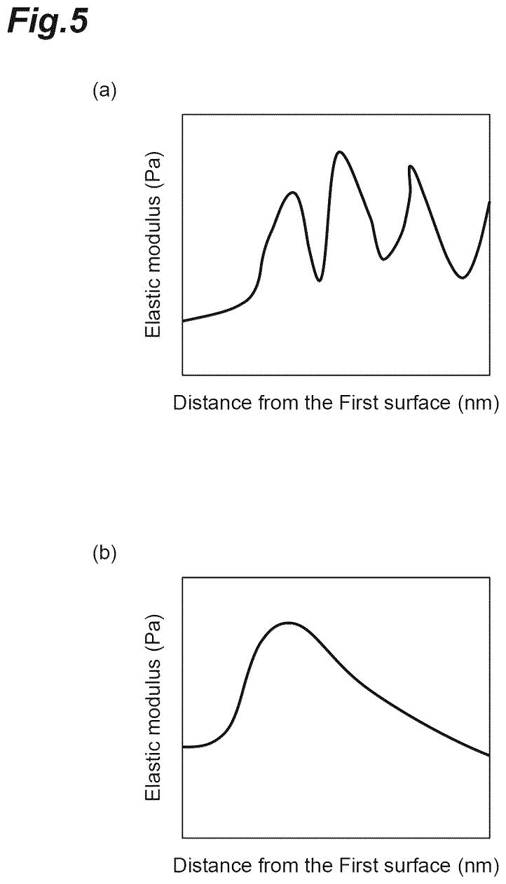

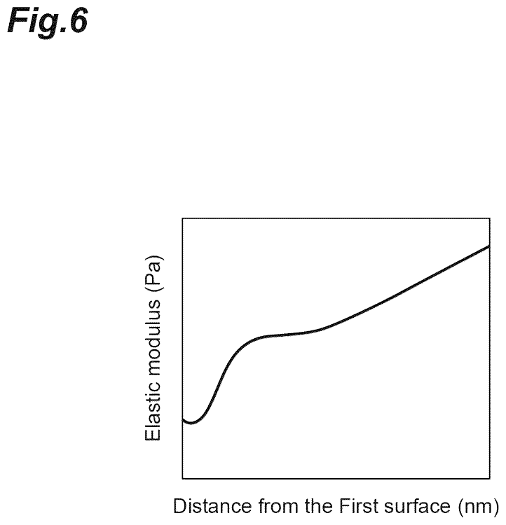

Since the indentation measurement using an atomic force microscope measures the local elastic modulus of the resin component at the first surface F1, there are cases where a result as shown in FIG. 2 cannot be obtained for the film-like adhesive agent 1. For example, if the cantilever comes into contact with the rubber component 1f during the indentation measurement, the elastic modulus of the resin component cannot be measured correctly, and a graph showing the relationship between the elastic modulus and the thickness of the film-like adhesive agent as shown in FIG. 2 cannot be obtained. If the measurement is not performed correctly, the indentation measurement may be performed again to check whether a graph as shown in FIG. 2 can be obtained. It should be noted that if a graph as shown in FIG. 2 is not obtained even once when the indentation measurement is performed 10 times on the film-like adhesive agent, it is determined that the film does not correspond to the film-like adhesive agent of the present case. Examples of graphs obtained when the indentation measurement is not performed correctly are shown in FIGS. 3 to 6.

Since the elastic modulus of the film-like adhesive agent differs between region A and region B, the behavior of the curve changes at the boundary between region A and region B. Therefore, the intersection of the G1 portion and the G2 portion of the curve can be regarded as the thickness a (μm) of the region A.

The thickness a of the region A is, for example, 0.05 to 2 μm, and may be 0.1 to 1.5 μm, 0.2 to 1.5 μm, or 0.3 to 1 μm. When the thickness a of the region A is 0.05 μm or more, the region A tends to be able to play a role of impeding the migration of heavy metal ions, and further, when the thickness a of the region A is 0.1 μm or more, the region A tends to be able to sufficiently play a role of impeding the migration of heavy metal ions. On the other hand, when the thickness a of the region A is 2 μm or less, the handleability of the film-like adhesive agent 1 tends to be easily maintained. The ratio of the thickness a of the region A to the total thickness of the film-like adhesive agent 1 is, for example, 0.3 to 25%, and may be 1 to 20% or 3 to 15%. When this ratio is 0.3% or more, the region A tends to be able to play a role of impeding the migration of heavy metal ions, and further, when this ratio is 1% or more, the region A tends to be able to sufficiently play a role of impeding the migration of heavy metal ions. On the other hand, when this ratio is 25% or less, an effect that the mechanical strength of the film-like adhesive agent 1 can be maintained is achieved.

Since the composition of the region B is uniform, the content of the rubber component 1f does not substantially change. Therefore, the G2 portion of the curve becomes flat, and the elastic modulus b at the intersection of the G1 portion and the G2 portion of the curve can be regarded as the elastic modulus of the region B.

The film-like adhesive agent 1 is constituted by an adhesive composition containing (A) a thermosetting resin component and (B) a rubber component. The film-like adhesive agent 1 may be one that can be in a cured (C-stage) state after a curing treatment via a semi-cured (B-stage) state.

### (Component (A): Thermosetting Resin)

Component (A) may be an epoxy resin from the viewpoint of adhesiveness. As the epoxy resin, any resin having an epoxy group in the molecule can be used without particular limitation. Examples of the epoxy resin include bisphenol A type epoxy resin, bisphenol F type epoxy resin, bisphenol S type epoxy resin, phenol novolac type epoxy resin, cresol novolac type epoxy resin, bisphenol A novolac type epoxy resin, bisphenol F novolac type epoxy resin, stilbene type epoxy resin, triazine skeleton-containing epoxy resin, fluorene skeleton-containing epoxy resin, triphenolmethane type epoxy resin, biphenyl type epoxy resin, xylylene type epoxy resin, biphenyl aralkyl type epoxy resin, naphthalene type epoxy resin, and diglycidyl ether compounds of polyfunctional phenols and polycyclic aromatics such as anthracene. These may be used singly or in combination of two or more. Among these, component (A) may be a cresol novolac type epoxy resin, a phenol novolac type epoxy resin, a bisphenol F type epoxy resin, or a bisphenol A type epoxy resin from the viewpoints of tackiness, flexibility, and the like of the film.

The epoxy equivalent of the epoxy resin is not particularly limited, but may be 90 to 300 g/eq or 110 to 290 g/eq. When the epoxy equivalent of the epoxy resin is within such a range, fluidity tends to be ensured while maintaining the bulk strength of the film-like adhesive agent.

The content of component (A), based on the total mass of the film-like adhesive agent (adhesive composition), is 15 to 80 mass %, and may be 20 to 75 mass %, 30 to 70 mass %, 30 to 60 mass %, or 35 to 50 mass %. When the content of component (A) is within such a range, it becomes easier to produce the film-like adhesive agent according to the present embodiment, and therefore, the migration (permeation) of heavy metal ions within the film-like adhesive agent is more sufficiently suppressed, and the adhesion tends to be excellent. When this content is 15 mass % or more, an effect that region A is easily formed is achieved, while when it is 80 mass % or less, an effect that workability in the production of the film-like adhesive agent is easily maintained is achieved.

### (Component (B): Rubber Component)

Examples of component (B) include acrylic rubber, isoprene rubber, butyl rubber, styrene-butadiene rubber, butadiene rubber, styrene-butylene-styrene rubber, styrene-ethylene-propylene-styrene rubber, styrene-ethylene-butylene-styrene rubber, acrylonitrile-butadiene rubber, silicone rubber, urethane rubber, chloroprene rubber, ethylene-propylene rubber, fluororubber, polysulfide rubber, epichlorohydrin rubber, and chlorinated butyl rubber. Component (B) may be one that is not compatible with component (A), and a part or all of component (B) may not be completely dissolved in component (A). Component (B) may be an acrylic rubber having a structural unit derived from a (meth)acrylic acid ester as a main component, from the viewpoint of making it easier to produce the film-like adhesive agent according to the present embodiment. The content of the structural unit derived from a (meth)acrylic acid ester in component (B), based on the total amount of structural units, may be, for example, 70 mass % or more, 80 mass % or more, or 90 mass % or more, from the viewpoint of making it easier to produce the film-like adhesive agent according to the present embodiment. The acrylic rubber may include a structural unit derived from a (meth)acrylic acid ester having a cross-linkable functional group such as an epoxy group, an alcoholic or phenolic hydroxyl group, or a carboxyl group. It may also include a structural unit derived from acrylonitrile, but from the viewpoint of being able to more sufficiently suppress the permeation of heavy metal ions within the film-like adhesive agent and also being more excellent in embedding properties, component (B) may be one that does not include a structural unit derived from acrylonitrile.

The glass transition temperature (Tg) of component (B) may be −50 to 50° C. or −30 to 30° C. When the Tg of component (B) is −50° C. or higher, it tends to be possible to prevent the flexibility of the film-like adhesive agent from becoming too high. This makes it easier to cut the film-like adhesive agent during wafer dicing, making it possible to prevent the occurrence of burrs. When the Tg of component (B) is 50° C. or lower, a decrease in the flexibility of the film-like adhesive agent tends to be suppressed. This tends to make it easier to sufficiently fill voids when attaching the film-like adhesive agent to a wafer. In addition, it becomes possible to prevent chipping during dicing due to a decrease in the adhesion of the wafer. Here, the glass transition temperature (Tg) means a value measured using a DSC (Differential Scanning calorimeter) (for example, Thermo Plus 2 manufactured by Rigaku Corporation).

The weight-average molecular weight (Mw) of component (B) may be 100,000 to 3,000,000 or 200,000 to 2,000,000. When the Mw of component (B) is within such a range, film formability, strength, flexibility, tackiness, and the like in the film-like adhesive agent can be appropriately controlled, and it is possible to have excellent reflow properties and improve embedding properties. Here, Mw means a value measured by gel permeation chromatography (GPC) and converted using a calibration curve based on standard polystyrene.

Examples of commercially available products for component (B) include SG-P3 modified product and SG-80H (both manufactured by Nagase ChemteX Corporation).

The content of component (B), based on the total mass of the film-like adhesive agent (adhesive composition), is 20 to 85 mass %, and may be 25 to 80 mass %, 20 to 65 mass %, 20 to 50 mass %, 20 to 40 mass %, or 30 to 70 mass %. When the content of component (B) is within such a range, it becomes easier to produce the film-like adhesive agent according to the present embodiment, and therefore, the migration (permeation) of heavy metal ions within the film-like adhesive agent is more sufficiently suppressed, and the adhesion tends to be excellent. When this content is 20 mass % or more, an effect that region A is easily formed is achieved, while when it is 85 mass % or less, an effect that workability in the production of the film-like adhesive agent is easily maintained is achieved.

The content of component (B) may be 5 to 80 parts by mass, 20 to 60 parts by mass, or 30 to 45 parts by mass, with respect to 100 parts by mass of the total mass of components (A) and (B). When the content of component (B) is 5 parts by mass or more, it becomes easier to produce the film-like adhesive agent according to the present embodiment, and therefore, the migration (permeation) of heavy metal ions within the film-like adhesive agent is more sufficiently suppressed, and the adhesion tends to be excellent. When the content of component (B) is 80 parts by mass or less, an effect that region A is easily formed is achieved, while when it is 85 mass % or less, an effect that workability in the production of the film-like adhesive agent is easily maintained is achieved.

The film-like adhesive agent (adhesive composition) may contain components other than (A) the thermosetting resin component and (B) the rubber component. For example, the film-like adhesive agent (adhesive composition) may further contain (C) a curing agent, (D) a filler, (E) a coupling agent, (F) a curing accelerator, and the like.

### (Component (C): Curing Agent)

Component (C) may be a phenol resin that can serve as a curing agent for the epoxy resin. As the phenol resin, any resin having a phenolic hydroxyl group in the molecule can be used without particular limitation. Examples of the phenol resin include novolac-type phenol resins obtained by condensing or co-condensing phenols such as phenol, cresol, resorcinol, catechol, bisphenol A, bisphenol F, phenylphenol, and aminophenol and/or naphthols such as α-naphthol, β-naphthol, and dihydroxynaphthalene with a compound having an aldehyde group such as formaldehyde under an acidic catalyst; phenol aralkyl resins synthesized from phenols such as allylated bisphenol A, allylated bisphenol F, allylated naphthalenediol, phenol novolac, and phenol and/or naphthols and dimethoxyparaxylene or bis(methoxymethyl) biphenyl; and naphthol aralkyl resins. These may be used singly or in combination of two or more. Among these, the phenol resin may be a novolac-type phenol resin or a naphthol aralkyl resin.

The hydroxyl equivalent of the phenol resin may be 70 g/eq or more, or 70 to 300 g/eq. When the hydroxyl equivalent of the phenol resin is 70 g/eq or more, the storage modulus of the film tends to be further improved, and when it is 300 g/eq or less, it is possible to prevent defects due to the generation of foaming, outgassing, and the like.

The ratio of the epoxy equivalent of the epoxy resin to the hydroxyl equivalent of the phenol resin (epoxy equivalent of epoxy resin/hydroxyl equivalent of phenol resin) may be 0.30/0.70 to 0.70/0.30, 0.35/0.65 to 0.65/0.35, 0.40/0.60 to 0.60/0.40, or 0.45/0.55 to 0.55/0.45 from the viewpoint of curability. When this equivalent ratio is 0.30/0.70 or more, more sufficient curability tends to be obtained. When this equivalent ratio is 0.70/0.30 or less, it is possible to prevent the viscosity from becoming too high, and more sufficient fluidity can be obtained.

The total content of components (A) and (C) may be 5 to 80 parts by mass, 20 to 80 parts by mass, 40 to 80 parts by mass, 60 to 80 parts by mass, 10 to 75 parts by mass, or 15 to 70 parts by mass, with respect to 100 parts by mass of the total mass of components (A), (B), and (C). When the total content of components (A) and (C) is 5 parts by mass or more, the elastic modulus tends to be improved by cross-linking, and in particular, the effect of improving the bulk elastic modulus is exhibited. When the total content of components (A) and (C) is 80 parts by mass or less, the handleability of the film tends to be maintained. When the tack of the film is strong, components (A) and (C) that are solid at room temperature may be used. When the tack of the film is weak, components (A) and (C) that are liquid at room temperature may be used.

In another embodiment, (A) the thermosetting resin component may include an elastomer having a cross-linkable functional group such as an epoxy group, an alcoholic or phenolic hydroxyl group, or a carboxyl group, and a curing agent that can react with the cross-linkable functional group. As a combination of the elastomer having a cross-linkable functional group and the curing agent that can react with the cross-linkable functional group, for example, a combination of an acrylic rubber having an epoxy group and a phenol resin can be mentioned.

### (Component (D): Filler)

The film-like adhesive agent (adhesive composition) may contain (D) a filler or may not contain (D) a filler. Component (D) may be either an inorganic filler or an organic filler. Examples of the inorganic filler include aluminum hydroxide, magnesium hydroxide, calcium carbonate, magnesium carbonate, calcium silicate, magnesium silicate, calcium oxide, magnesium oxide, aluminum oxide, aluminum nitride, aluminum borate whiskers, boron nitride, and silica. These may be used singly or in combination of two or more. Among these, component (D) may be silica from the viewpoint of adjusting the melt viscosity. Examples of the organic filler include carbon, rubber-based fillers, silicone-based fine particles, polyamide fine particles, and polyimide fine particles. The shape of component (D) is not particularly limited, but may be spherical.

The average particle size of component (D) may be 0.01 to 1 μm, 0.01 to 0.8 μm, or 0.03 to 0.5 μm from the viewpoint of fluidity. Here, the average particle size means a value obtained by conversion from the BET specific surface area.

The content of component (D) may be 0.1 to 50 parts by mass, 0.1 to 30 parts by mass, or 0.1 to 20 parts by mass, with respect to 100 parts by mass of the total mass of components (A), (B), and (C). Based on the total mass of the film-like adhesive agent (adhesive composition), the content of component (D) is, for example, 3 to 55 mass %, and may be 5 to 50 mass % or 7 to 40 mass %. When this content is 3 mass % or more, an effect that the mechanical strength of the film-like adhesive agent can be maintained is achieved, while when it is 55 mass % or less, an effect that a good appearance of the film-like adhesive agent is maintained is achieved.

### (Component (E): Coupling Agent)

Component (E) may be a silane coupling agent. Examples of the silane coupling agent include γ-ureidopropyltriethoxysilane, γ-mercaptopropyltrimethoxysilane, 3-phenylaminopropyltrimethoxysilane, 3-(2-aminoethyl)aminopropyltrimethoxysilane, and the like. These may be used singly or in combination of two or more.

### (Component (F): Curing Accelerator)

Component (F) is not particularly limited, and commonly used ones can be used. Examples of component (F) include imidazoles and derivatives thereof, organophosphorus compounds, secondary amines, tertiary amines, quaternary ammonium salts, and the like. These may be used singly or in combination of two or more. Among these, from the viewpoint of reactivity, component (F) may be imidazoles and derivatives thereof. Examples of imidazoles include 2-methylimidazole, 1-benzyl-2-methylimidazole, 1-cyanoethyl-2-phenylimidazole, 1-cyanoethyl-2-methylimidazole, and the like. These may be used singly or in combination of two or more.

The film-like adhesive agent 1 may further contain other components. Examples of other components include leveling agents, pigments, ion scavengers, antioxidants, and the like. The content of component (E), component (F), and other components may be 0 to 30 parts by mass with respect to 100 parts by mass of the total mass of component (A), component (B), and component (C).

### <Method for Producing Film-Like Adhesive Agent>

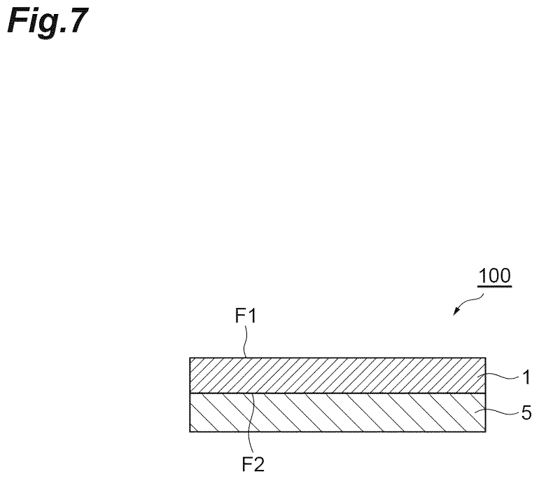

The film-like adhesive agent 1 can be formed by applying an adhesive composition to a support film. When a varnish of the adhesive composition (adhesive varnish) is used, the film-like adhesive agent 1 can be obtained through a process of mixing component (A) and component (B), as well as other components added as necessary, in a solvent, mixing or kneading the mixed liquid to prepare an adhesive varnish, applying the adhesive varnish to the support film 5, and removing the solvent by drying. The adhesive sheet 100 shown in FIG. 7 is constituted by the support film 5 and the film-like adhesive agent 1 provided on the surface of the support film 5.

When forming the film-like adhesive agent 1 from a coating film of the adhesive varnish, by removing the solvent by drying while blowing air onto the surface of the coating film, it becomes easier to produce the film-like adhesive agent according to the present embodiment. The speed of the wind flowing parallel to the upper surface of the coating film is, for example, 3 to 20 m/sec. When this speed is 3 m/sec or more, the drying of component (A) on the surface of the coating film to which the wind is applied is promoted, making it easier to produce the film-like adhesive agent according to the present embodiment, and an effect is achieved that the region A having a sufficient thickness is easily formed in the vicinity of the first surface F1 of the film-like adhesive agent 1. On the other hand, when it is 20 m/sec or less, an effect is achieved that the appearance of the coating film surface is easily maintained well.

The drying temperature of the adhesive varnish is, for example, 25 to 150° C., and may be 60 to 145° C. or 70 to 140° C. When the drying temperature is 70° C. or higher, an effect is achieved that it is easier to produce the film-like adhesive agent according to the present embodiment, while when it is 150° C. or lower, an effect is achieved that poor appearance is easily suppressed.

The support film 5 is not particularly limited as long as it can withstand the above-mentioned heat drying, but may be, for example, a polyester film, a polypropylene film, a polyethylene terephthalate film, a polyimide film, a polyetherimide film, a polyether naphthalate film, a polymethylpentene film, or the like. The support film 5 may be a multilayer film combining two or more types, and its surface may be treated with a release agent such as a silicone-based or silica-based agent. The thickness of the support film 5 may be, for example, 10 to 200 μm or 20 to 170 μm.

Mixing or kneading can be performed using a normal stirrer, a mortar and pestle, a three-roll mill, a ball mill, or other dispersing machines, by appropriately combining them. The solvent used for preparing the adhesive varnish is not limited as long as it can uniformly dissolve, knead, or disperse each component, and conventionally known ones can be used. Examples of such a solvent include ketone-based solvents such as acetone, methyl ethyl ketone, methyl isobutyl ketone, and cyclohexanone, dimethylformamide, dimethylacetamide, N-methyl-2-pyrrolidone, toluene, xylene, and the like. The solvent may be methyl ethyl ketone, cyclohexanone, or the like from the viewpoint of fast drying speed and low cost. As a method for applying the adhesive varnish to the support film, a known method can be used, and examples include a knife coating method, a roll coating method, a spray coating method, a gravure coating method, a bar coating method, a curtain coating method, and the like.

### <Dicing/Die-Bonding Integrated Film>

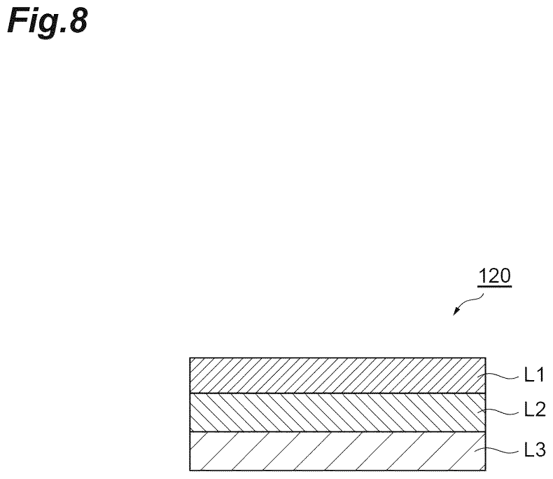

FIG. 8 is a schematic cross-sectional view of a dicing/die-bonding integrated film including the film-like adhesive agent 1. The dicing/die-bonding integrated film 120 shown in this figure includes, in this order, a first adhesive layer L1 composed of the film-like adhesive agent 1, a second adhesive layer L2 in contact with the second surface F2 of the film-like adhesive agent 1, and a base film L3 in contact with the second adhesive layer L2. The second adhesive layer L2 and the base film L3 constitute a dicing tape.

### <Semiconductor Device>

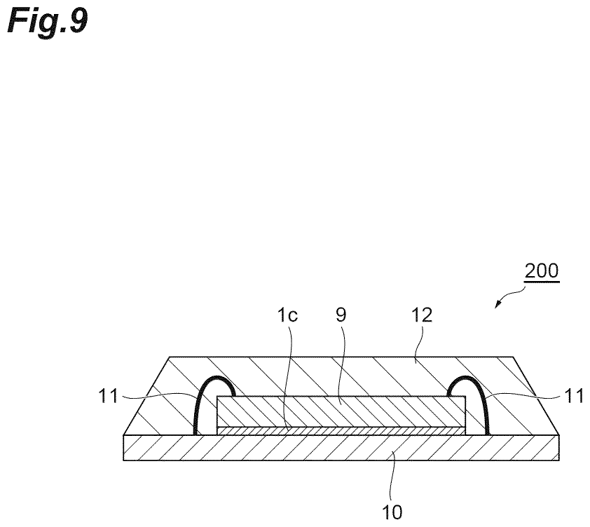

Using the dicing/die-bonding integrated film 120, for example, a semiconductor device shown in FIG. 9 can be produced. The semiconductor device 200 shown in FIG. 9 includes a semiconductor chip 9, a support member 10 on which the semiconductor chip 9 is mounted, and a cured product 1c of an adhesive piece provided between the semiconductor chip 9 and the support member 10. The adhesive piece is the singulated film-like adhesive agent 1. The cured product 1c adheres the semiconductor chip 9 and the support member 10. Connection terminals (not shown) of the semiconductor chip 9 are electrically connected to external connection terminals (not shown) via wires 11 and are sealed with an encapsulant 12.

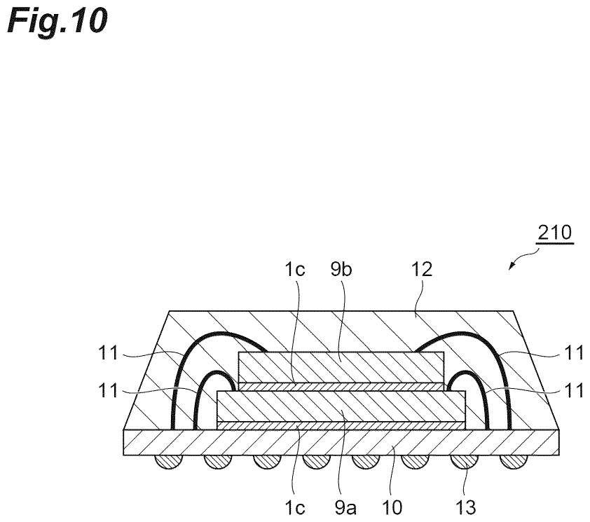

A semiconductor device shown in FIG. 10 can also be produced using the dicing/die-bonding integrated film 120. In the semiconductor device 210 shown in FIG. 10, a first-stage semiconductor chip 9a is adhered to a support member 10 by a cured product 1c, and a second-stage semiconductor chip 9b is further adhered onto the first-stage semiconductor chip 9a by a cured product 1c. Connection terminals (not shown) of the first-stage semiconductor chip 9a and the second-stage semiconductor chip 9b are electrically connected to external connection terminals via wires 11 and are sealed with an encapsulant 12. A terminal 13 is formed on the lower surface of the support member 10.

### <Method for Producing Semiconductor Device>

The semiconductor devices 200, 210 are produced, for example, through the following steps.

A step of attaching a wafer onto the first surface F1 of the first adhesive layer L1 (film-like adhesive agent) in the dicing/die-bonding integrated film 120.

A step of singulating the wafer and the first adhesive layer L1 (film-like adhesive agent) into a plurality of chips each with an adhesive piece.

A step of picking up the chip with an adhesive piece from the second adhesive layer L2.

A step of pressure-bonding the semiconductor chip onto a substrate or another semiconductor chip via the adhesive piece.

The semiconductor devices 200, 210 are obtained, for example, by interposing an adhesive piece between a semiconductor chip and a support member or between a semiconductor chip and another semiconductor chip, heat-pressure-bonding them to adhere both, and then, as necessary, going through a wire bonding step, a sealing step with an encapsulant, a heat-melting step including reflow with solder, and the like. The heating temperature in the heat-pressure-bonding step is usually 20 to 250° C., the load is usually 0.1 to 200 N, and the heating time is usually 0.1 to 300 seconds.

The support member may include a member made of copper as a material. Since the semiconductor devices 200, 210 are produced using the film-like adhesive agent 1 which has a barrier function that impedes the migration of heavy metal ions (for example, copper ions), even when a member made of copper as a material is used as a constituent member of the semiconductor device, the influence of copper ions generated from the member can be reduced, and the occurrence of electrical defects caused by copper ions can be sufficiently suppressed. Here, examples of the member made of copper as a material include a lead frame, wiring, wires, heat dissipation materials, and the like, but regardless of which member uses copper, it is possible to reduce the influence of copper ions.

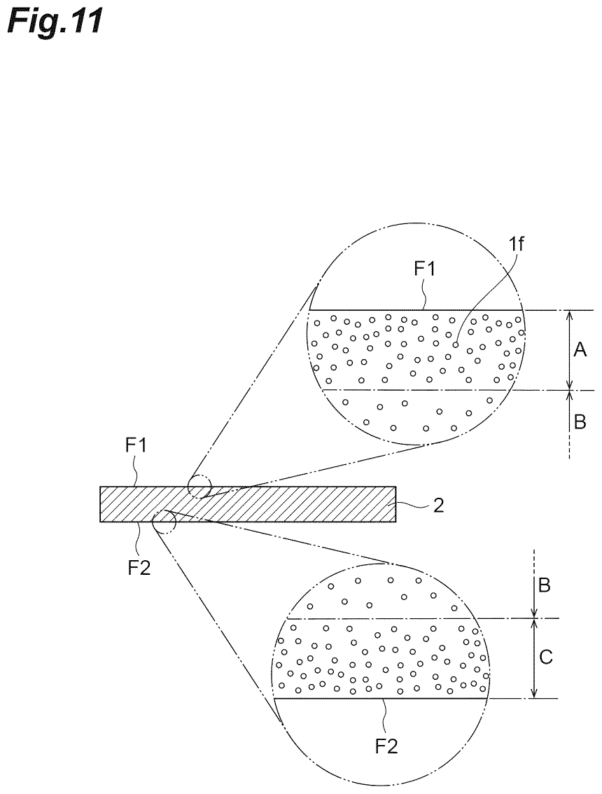

Although the embodiments of the present disclosure have been described in detail above, the present disclosure is not limited to the above embodiments. For example, in the above embodiments, an aspect in which the region A is formed in the vicinity of the first surface F1 was exemplified, but as shown in FIG. 11, a region C similar to the region A may also be formed in the vicinity of the second surface F2. The film-like adhesive agent 2 shown in the same figure has the same configuration as the film-like adhesive agent 1, except that it further has a region C, which is a region in the vicinity of the second surface F2, where the content of the rubber component increases from the first surface F1 side toward the second surface F2 side. The region C is located at a position shallower than a position at a depth of 2 μm from the second surface F2. In other words, “in the vicinity of the second surface F2” means a region shallower than a position at a depth of 2 μm from the second surface F2. It should be noted that it is sufficient that the region C exists in the vicinity of the second surface F2, and for example, a region where the content of the rubber component is small may exist locally on the second surface F2.

The thickness of the film-like adhesive agent 2 may be 50 μm or less, and may be, for example, 40 μm or less, 30 μm, 20 μm or less, or 10 μm or less. When the thickness of the film-like adhesive agent 2 is 50 μm or less, the distance between a semiconductor element and a support member on which the semiconductor element is mounted becomes shorter, which tends to make defects due to heavy metal ions more likely to occur, and thus the effects of the present invention are more easily obtained. The lower limit of the thickness of the film-like adhesive agent 2 is not particularly limited, but can be, for example, 2 μm or more. When the thickness of the film-like adhesive agent 2 is 2 μm or more, a film with a better appearance tends to be more easily obtained. The thickness of the region C is, for example, 0.05 to 2 μm, and may be 0.1 to 1.5 μm, 0.2 to 1.5 μm, or 0.3 to 1 μm. When the thickness of the region C is 0.05 μm or more, the region C tends to be able to play a role of impeding the migration of heavy metal ions, and further, when the thickness of the region C is 0.1 μm or more, the region C tends to be able to sufficiently play a role of impeding the migration of heavy metal ions. On the other hand, when the thickness of the region C is 2 μm or less, an effect is achieved that the handleability of the film-like adhesive agent 2 is easily maintained. The ratio of the thickness of the region C to the total thickness of the film-like adhesive agent 2 is, for example, 0.3 to 25%, and may be 1 to 20% or 3 to 15%. When this ratio is 0.3% or more, the region C tends to be able to play a role of impeding the migration of copper ions. Furthermore, when this ratio is 1% or more, the region C tends to be able to sufficiently play a role of impeding the migration of heavy metal ions. On the other hand, when this ratio is 25% or less, an effect that the mechanical strength of the film-like adhesive agent 2 can be maintained is achieved.

The present disclosure relates to the following matters.
[1] A film-like adhesive agent composed of a resin composition having a thermosetting property and containing a rubber component, the film-like adhesive agent having a first surface and a second surface, wherein:
   the film-like adhesive agent has a region in a vicinity of the first surface, in which a content of the rubber component increases from a side of the second surface toward a side of the first surface; and
   a graph obtained by indentation measurement using an atomic force microscope conducted according to the following procedure has: a portion G1 in which an elastic modulus gradually increases starting from a measurement result at the first surface; and a portion G2 in which the elastic modulus is substantially constant from an end point of the portion G1.

### (Procedure for Indentation Measurement Using an Atomic Force Microscope)

(1) Cure the film-like adhesive agent, fix the cured film-like adhesive agent on a sample stage of an atomic force microscope, and align a tip of a cantilever having a radius of curvature of 10 nm or less so as to be perpendicular to the first surface of the cured film-like adhesive agent.
(2) Measurement is performed in a contact mode by pressing the cantilever to obtain a curve showing the relationship between the applied load and the indentation depth.
(3) Obtain the graph showing the relationship between an elastic modulus of the film-like adhesive agent and a distance from the first surface, from the curve, by using Hertz contact theory.
[2] The film-like adhesive agent according to [1], wherein a thickness of the region is 2 μm or less.
[3] The film-like adhesive agent according to [1] or [2], wherein a ratio of a thickness of the region to a total thickness of the film-like adhesive agent is 0.3 to 25%.
[4] The film-like adhesive agent according to any one of [1] to [3], wherein the region is located at a position shallower than a position at a depth of 2 μm from the first surface.
[5] The film-like adhesive agent according to any one of [1] to [4], wherein, based on a total mass of the resin composition, a content of the rubber component is from 20 mass % to 85 mass %.
[6] The film-like adhesive agent according to any one of [1] to [5], wherein the rubber component is acrylic rubber.
[7] The film-like adhesive agent according to any one of [1] to [6], wherein the film-like adhesive agent has a single-layer structure.
[8] An adhesive film, including:
   the film-like adhesive agent according to any one of [1] to [7]; and
   a base film in contact with the second surface of the film-like adhesive agent.
[9] A dicing/die-bonding integrated film, including in this order:
   a first adhesive layer composed of the film-like adhesive agent according to any one of [1] to [7];
   a second adhesive layer in contact with the second surface of the film-like adhesive agent; and
   a base film in contact with the second adhesive layer.
[10] A method for producing a semiconductor device, including:
   a step of attaching a wafer onto the first surface of the film-like adhesive agent in the dicing/die-bonding integrated film according to [9];
   a step of singulating the wafer and the film-like adhesive agent into a plurality of chips each with an adhesive piece;
   a step of picking up the chip with an adhesive piece from the second adhesive layer; and
   a step of pressure-bonding the chip onto a substrate or another chip via the adhesive piece.

### EXAMPLES

Hereinafter, the present disclosure will be specifically described based on Examples and Comparative Examples. The present invention is not limited to the following Examples.

### [Production of Film-Like Adhesive Agent]

### <Preparation of Adhesive Varnish>

An acrylic rubber solution shown in Table 1 was used as an adhesive varnish. The numerical values related to the composition shown in Table 1 mean parts by mass of the solid content of the acrylic rubber solution.

### Epoxy Resin

HP-4710 (trade name, manufactured by DIC Corporation, naphthalene type epoxy resin, epoxy equivalent: 170 g/eq)
N-500P-10 (trade name, manufactured by DIC Corporation, o-cresol novolac type epoxy resin, epoxy equivalent: 203 g/eq)
EXA-830CRP (trade name, manufactured by DIC Corporation, bisphenol F type epoxy resin, epoxy equivalent: 155-163 g/eq)

### Curing Agent (Phenol Resin)

PSM-4326 (trade name, manufactured by Gun Ei Chemical Industry Co., Ltd., softening point: 120° C.)

### Acrylic Rubber

SG-P3 modified product (trade name, manufactured by Nagase ChemteX Corporation)

### Coupling Agent

Z-6119 (trade name, manufactured by Dow Toray Co., Ltd., 3-ureidopropyltriethoxysilane)
A-189 (trade name, manufactured by Nippon Unicar Company Limited, γ-mercaptopropyltrimethoxysilane)

### Curing Accelerator

2PZ (trade name, manufactured by Shikoku Chemicals Corporation, 2-phenylimidazole)

### <Production of Film-Like Adhesive Agent>

The adhesive varnish with the composition shown in Table 1 was filtered through a 100-mesh filter and vacuum-defoamed. A polyethylene terephthalate (PET) film with a thickness of 38 μm subjected to release treatment was prepared as a base film, and the adhesive varnish after vacuum defoaming was applied onto the PET film. The application amount of the adhesive varnish was adjusted so that the thickness after drying would be 20 μm. The applied adhesive varnish was dried at a drying temperature of 110° C. with air blowing at a speed of 3 m/sec or more parallel to the upper surface of the coating film, thereby obtaining three film-like adhesive agents in a B-stage state.

### [Indentation Measurement Using Atomic Force Microscope]

The three film-like adhesive agents were heated at 175° C. for 5 hours and cured, respectively. Next, the cured film-like adhesive agent was fixed on a sample stage of an atomic force microscope (SPM400, manufactured by Hitachi High-Tech Corporation), a cantilever (manufactured by Hitachi High-Tech Corporation, trade name SI-DF-40, material Si, spring constant 40 N/m, tip radius of curvature 8 nm) was set in a cantilever holder, the cantilever was pressed in, and a force curve of the region where the cantilever was being pressed into the sample (cured film-like adhesive agent) was obtained. From the obtained force curve, a graph showing the relationship between the elastic modulus and the thickness of the film-like adhesive agent (indentation depth of the cantilever) was obtained using Hertz contact theory. At this time, a corrected cantilever spring constant was used, and the measurement was performed while monitoring the state of the cantilever and confirming that there was no obvious wear and deterioration. For one film-like adhesive agent (Example 1), a graph (a graph as shown in FIG. 2) was obtained which has a portion G1 in which the elastic modulus gradually increases starting from the measurement result at the first surface, and a portion G2 in which the elastic modulus is substantially constant from the end point of the portion G1. On the other hand, for the remaining two film-like adhesive agents (Comparative Examples 1, 2), such a graph could not be obtained. In the graph obtained from the film-like adhesive agent of Example 1, the length from the surface of the film to the intersection of the G1 portion and the G2 portion (the thickness of the region where the content of the rubber component increases) was 230 nm, and the ratio of the thickness of the region to the total thickness of the film-like adhesive agent was 1.15%.

### [Evaluation of Copper Ion Permeation Suppression Effect]

### <Preparation of Solution A>

2.0 g of anhydrous copper (II) sulfate was dissolved in 1020 g of distilled water and stirred until the copper sulfate was completely dissolved to prepare a copper sulfate aqueous solution with a copper ion concentration of 500 mg/kg in terms of Cu element. The obtained copper sulfate aqueous solution was designated as Solution A.

### <Preparation of Solution B>

1.0 g of anhydrous sodium sulfate was dissolved in 1000 g of distilled water and stirred until the sodium sulfate was completely dissolved. To this, 1000 g of N-methyl-2-pyrrolidone (NMP) was further added and stirred. Thereafter, it was air-cooled to room temperature to obtain a sodium sulfate aqueous solution. The obtained solution was designated as Solution B.

### <Measurement of Copper Ion Permeation Time>

The film-like adhesive agents (thickness: 10 μm) produced above were cured and then cut into circular shapes with a diameter of about 3 cm, respectively. Next, two silicone packing sheets with a thickness of 1.5 mm, an outer diameter of about 3 cm, and an inner diameter of 1.8 cm were prepared. The circularly cut film-like adhesive agent was sandwiched between the two silicone packing sheets, and this was sandwiched between the flange portions of two 50 mL volume glass cells and fixed with a rubber band.

Next, after injecting 50 g of Solution A into one glass cell, 50 g of Solution B was injected into the other glass cell. As carbon electrodes, Mars Carbon (manufactured by STAEDTLER Mars GmbH & Co. KG, o2 mm/130 mm) were inserted into each cell. The Solution A side was made the anode and the Solution B side was made the cathode, and the anode was connected to a DC power supply (manufactured by A&D Company, Limited, DC power supply AD-9723D). The cathode was connected in series to the DC power supply via an ammeter (manufactured by Sanwa Electric Instrument Co., Ltd., Digital multimeter PC-720M). At room temperature, a voltage of 24.0 V was applied, and the measurement of the current value was started after the application. The measurement time was set to 500 minutes, and the time for the current value to rise was taken as the copper ion permeation time. The rise time was defined as the time when the current value reached 1.0 μA. In this evaluation, the later the time for the current value to rise, the more the copper ion permeation is suppressed. Evaluation was made according to the following criteria. The results are shown in Table 1.
A: The copper ion permeation time is 100 minutes or more.
B: The copper ion permeation time is less than 100 minutes.

### [Evaluation of Adhesion]

The adhesive varnish side of the film-like adhesive agent produced above was attached to a glass plate with a cleaned surface (manufactured by Matsunami Glass Ind., Ltd., trade name: S1225) to obtain a sample. After the sample was left to stand on a hot plate at 60° C. for 1 minute, the sample was returned to room temperature (25° C.), and the PET film was peeled off. A support tape (manufactured by Oji Tac Co., Ltd., trade name: EC tape) was attached to the peeled surface of the PET film to prepare an evaluation sample with a width of 15 mm and a length of 75 mm. For the measurement of peel strength, an adhesion/film peel analyzer (manufactured by Kyowa Interface Science Co., Ltd., trade name: VPA-3) was used. For the peel strength, the rotating stage was moved and the scale of the angle adjustment part was set to 30° (that is, the peel strength is the peel strength at a peel angle of) 30°. The evaluation sample was peeled for several centimeters at the interface between the film-like adhesive agent and the support tape, a peel-inducing tape (manufactured by Oji Tac Co., Ltd., EC tape) cut to a width of 10 mm was attached to the tip on the film-like adhesive agent side, and fixed to the tip of a load cell. The position of the load cell was finely adjusted so that the peel progression was parallel to the tape width. The peel strength was measured by pulling 70 mm at a speed of 150 mm/min, the average value of the region where the peel distance was 40 to 70 mm was determined from the obtained measurement chart, and this average value was taken as the peel strength. The results are shown in Table 1.

TABLE 1

| | | |
|---|---|---|
| | Comparative | Comparative |
| Example 1 | Example 1 | Example 2 |

| | | |
|---|---|---|
| Composition | HP-4710 | 2 |
| (parts | N-500P-10 | 27 |
| by mass) | EXA-830CRP | 12 |
| | PSM-4326 | 26 |
| | SG-P3 improved | 33 |
| | product | |
| | Z-6119 | 0.2 |
| | A-189 | 0.1 |
| | 2PZ | 0.3 |

| | | | |
|---|---|---|---|
| Copper ion permeation | A | A | A |
| suppression effect | | | |
| Peel strength (N/10 mm) | 8.8 | 4.7 | 6.7 |

### REFERENCE SIGNS LIST

1, 2 . . . film-like adhesive agent, 1c . . . cured product, 5 . . . support film, 9, 9a, 9b . . . semiconductor chip, 10 . . . support member, 11 . . . wire, 12 . . . encapsulant, 13 . . . terminal, 100 . . . adhesive sheet, 120 . . . dicing/die-bonding integrated film, F1 . . . first surface, F2 . . . second surface, L1 . . . first adhesive layer (film-like adhesive agent), L2 . . . second adhesive layer, L3 . . . base film, A, B, C . . . region.

1. A film-like adhesive agent composed of a resin composition having a thermosetting property and comprising a rubber component, the film-like adhesive agent having a first surface and a second surface, wherein:
the film-like adhesive agent has a region in a vicinity of the first surface, in which a content of the rubber component increases from a side of the second surface toward a side of the first surface; and
a graph obtained by indentation measurement using an atomic force microscope conducted has: a first portion in which an elastic modulus gradually increases starting from a measurement result at the first surface; and a second portion in which the elastic modulus is substantially constant from an end point of the first portion, and
wherein the graph is obtained by:
(1) curing the film-like adhesive agent, fixing the cured film-like adhesive agent on a sample stage of the atomic force microscope, and setting a cantilever in a cantilever holder;
(2) pressing the cantilever to obtain a curve showing a relationship between an applied load and an indentation depth; and
(3) obtaining the graph showing a relationship between an elastic modulus of the film-like adhesive agent and a distance from the first surface, from the curve, by using Hertz contact theory.

2. The film-like adhesive agent according to claim 1, wherein a thickness of the region is 2 μm or less.

3. The film-like adhesive agent according to claim 1, wherein a ratio of a thickness of the region to a total thickness of the film-like adhesive agent is from 0.3% to 25%.

4. The film-like adhesive agent according to claim 1, wherein the region is located at a depth of less than 2 μm from the first surface.

5. The film-like adhesive agent according to claim 1, wherein, based on a total mass of the resin composition, the content of the rubber component is from 20 mass % to 85 mass %.

6. The film-like adhesive agent according to claim 1, wherein the rubber component is acrylic rubber.

7. The film-like adhesive agent according to claim 1, wherein the film-like adhesive agent has a single-layer structure.

8. An adhesive film comprising:
the film-like adhesive agent according to claim 1; and
a base film in contact with the second surface of the film-like adhesive agent.

9. A dicing/die-bonding integrated film comprising, in this order:
a first adhesive layer composed of the film-like adhesive agent according to claim 1;
a second adhesive layer in contact with the second surface of the film-like adhesive agent; and
a base film in contact with the second adhesive layer.

10. A method for producing a semiconductor device comprising:
a step of attaching a wafer onto the first surface of the film-like adhesive agent in the dicing/die-bonding integrated film according to claim 9;
a step of singulating the wafer and the film-like adhesive agent into a plurality of chips each with a first adhesive piece;
a step of picking up the chip with a second adhesive piece from the second adhesive layer; and
a step of pressure-bonding the chip onto a substrate or another chip via the adhesive piece.

11. The film-like adhesive agent according to claim 1, wherein a thickness of the region is 0.3 to 1 μm.

12. The film-like adhesive agent according to claim 1, wherein the film-like adhesive agent comprises a curing agent.

13. The film-like adhesive agent according to claim 1, wherein the film-like adhesive agent comprises a filler.

14. The film-like adhesive agent according to claim 13, wherein an average particle diameter of the filler is 0.01 to 1 μm.

15. The film-like adhesive agent according to claim 13, wherein a content of the filler is 7 to 40 mass % based on a total mass of the film-like adhesive agent.

16. The film-like adhesive agent according to claim 1, wherein the film-like adhesive agent comprises a coupling agent.

17. The film-like adhesive agent according to claim 1, wherein the film-like adhesive agent comprises a curing accelerator.

18. The film-like adhesive agent according to claim 1, wherein a thickness of the film-like adhesive agent is 50 μm or less.
